(19) United States
(12) Patent Application Publication
(10) Pub. No.: US 2026/0190785 A1
(43) Pub. Date: Jul. 2, 2026

(54) DISPLAY DEVICE

(71) Applicant: LG Display Co., Ltd., Seoul (KR)

(72) Inventors: Chanwoong JANG, Suwon-si (KR); Sungwoo JUN, Gimpo-si (KR); Jungdoo JIN, Paju-si (KR); Sungki HONG, Incheon (KR); Sehee KIM, Gangneung-si (KR)

(73) Assignee: LG Display Co., Ltd., Seoul (KR)

(21) Appl. No.: 19/410,537

(22) Filed: Dec. 5, 2025

(30) Foreign Application Priority Data
Dec. 30, 2024 (KR) 10-2024-0200139

(51) Int. Cl. H10K 59/80; H10K 59/40

(52) U.S. Cl. CPC H10K 59/873; H10K 59/40

(57) ABSTRACT

A display device includes a substrate having an active area and a non-active area adjacent to the active area. The non-active area includes a dam area in which at least one dam is disposed. An encapsulation layer is disposed on the substrate in the active area and the dam area. A first touch buffer layer is disposed on the encapsulation layer in the dam area, and a first touch electrode line is disposed on the first touch buffer layer. A second touch buffer layer is disposed on the first touch electrode line, and a touch interlayer insulating layer is disposed on the second touch buffer layer. A second touch electrode line is disposed on the touch interlayer insulating layer. The second touch buffer layer includes an inorganic insulating material, and the touch interlayer insulating layer includes an organic insulating material.

### CROSS-REFERENCE TO RELATED APPLICATIONS

This application claims the priority of Korean Patent Application No. 10-2024-0200139 filed on Dec. 30, 2024, in the Korean Intellectual Property Office, the disclosure of which is incorporated herein by reference.

### BACKGROUND

### Technical Field

The present disclosure relates to a display device, and more particularly, to a display device in which a touch electrode is disposed on an encapsulation layer.

### Description of the Related Art

As the information society develops, the demand for display devices that display images is increasing, and various types of display devices such as liquid crystal displays and organic light-emitting displays are being utilized.

The display device may recognize a user's touch on a display panel and perform input processing based on the recognized touch to provide a wider range of functions to the user. For example, a plurality of touch electrodes may be disposed in an active area of the display panel.

In addition, the display device may sense touch by detecting a change in capacitance of a touch electrode caused by the user's touch.

In particular, when the touch electrode is applied to an organic light-emitting display device, the elements constituting the touch element may be formed above or below an encapsulation layer for protecting the light-emitting element of the organic light-emitting display device.

### BRIEF SUMMARY

The present disclosure relates to a display device with integrated touch functionality in which a touch electrode structure is formed directly on the encapsulation layer of an organic light emitting diode display. By positioning the touch electrode above the encapsulation, the design achieves a thinner and more integrated display stack while maintaining electrical isolation and mechanical flexibility. This configuration also simplifies manufacturing for foldable and flexible devices by eliminating the need for separate touch substrates.

One of the features of the disclosure is a multi layer buffer and insulating structure that prevents plasma or chemical damage during the electrode formation process. The stack includes a first touch buffer layer made of an organic insulating material with a low dielectric constant, a second touch buffer layer formed of an inorganic material such as silicon nitride or silicon oxide, and a touch interlayer insulating layer composed of an organic resin. Together, these layers suppress damage and moisture infiltration into the encapsulated light emitting elements, extending the operational lifespan of the device and maintaining display reliability.

The design further includes overlapping encapsulation and touch electrode lines across a dam area positioned in the non active region of the display. This laminated structure covers the sides and tops of the dams, sealing the boundary between active and non active areas to block moisture penetration and prevent defects in the encapsulation layers. Combined with a plasma shielding process during etching, these structural and process features enhance durability, reduce electrical leakage and parasitic capacitance, and enable stable operation with improved touch performance.

Various embodiments of the present disclosure provide a display device capable of suppressing moisture penetration from a non-active area in a structure in which a touch electrode is disposed on an encapsulation layer.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display device. The display device includes a substrate including an active area and a non-active area positioned around the active area and including a dam area, at least one dam being disposed in the dam area. The display device further includes an encapsulation layer disposed in the active area and the dam area on the substrate. The display device further includes a first touch buffer layer disposed on the encapsulation layer in the dam area. The display device further includes a first touch electrode line disposed on the first touch buffer layer in the dam area. The display device further includes a second touch buffer layer disposed on the first touch electrode line in the dam area. The display device further includes a touch interlayer insulating layer disposed on the second touch buffer layer in the dam area. The display device further includes a second touch electrode line disposed on the touch interlayer insulating layer in the dam area. The second touch buffer layer includes an inorganic insulating material, and the touch interlayer insulating layer includes an organic insulating material.

According to another aspect of the present disclosure, there is provided a display device. The display device includes a substrate including an active area and a dam area positioned around the active area and having at least one dam disposed in the dam area. The display device further includes an encapsulation layer disposed in the active area and the dam area on the substrate. The display device further includes a first touch buffer layer disposed on the encapsulation layer. The display device further includes a first touch electrode line disposed on the first touch buffer layer. The display device further includes a second touch buffer layer disposed on the first touch electrode line. The display device further includes a touch interlayer insulating layer disposed on the second touch buffer layer. The display device further includes a second touch electrode line disposed on the touch interlayer insulating layer. The encapsulation layer, the first touch buffer layer, the first touch electrode line, the second touch buffer layer, the touch interlayer insulating layer, and the second touch electrode line each overlap a side surface and a top surface of the at least one dam.

Other detailed matters of the exemplary embodiments are included in the detailed description and the drawings.

According to an embodiment of the present disclosure, the plurality of touch electrode lines and the plurality of insulating layers are disposed in the non-active area. Therefore, it is possible to suppress occurrence of defects in the encapsulation layer disposed in the non-active area and improve the lifespan of a light-emitting diode and provide the display device capable of low-power operation.

The effects of the present disclosure are not limited to the aforementioned effects, and other effects, which are not mentioned above, will be apparently understood to a person having ordinary skill in the art from the following description.

The technical benefits to be achieved by the present disclosure, the means for achieving the benefits, and the effects of the present disclosure described above do not specify essential features of the claims, and, thus, the scope of the claims is not limited to the disclosure of the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a system configuration diagram of a display device according to embodiments of the present disclosure.

FIG. 2 is a schematic diagram of a display panel of a touch screen-integrated light-emitting display device according to embodiments of the present disclosure.

FIG. 3 is an exemplary diagram illustrating a structure in which a touch panel is embedded in the display panel according to embodiments of the present disclosure.

FIG. 4 is a cross-sectional view taken along line A-B of FIG. 2.

FIG. 5 is a cross-sectional view taken along line C-D of FIG. 2.

FIG. 6 is a diagram illustrating a process sequence for forming components disposed on an encapsulation layer in a non-active area.

FIG. 7 is a cross-sectional view illustrating a non-active area of a display device according to another embodiment of the present disclosure.

FIG. 8 is an image illustrating a portion of a dam area of a display device according to a comparative example.

FIG. 9 is an image illustrating a portion of a dam area of a display device according to an embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

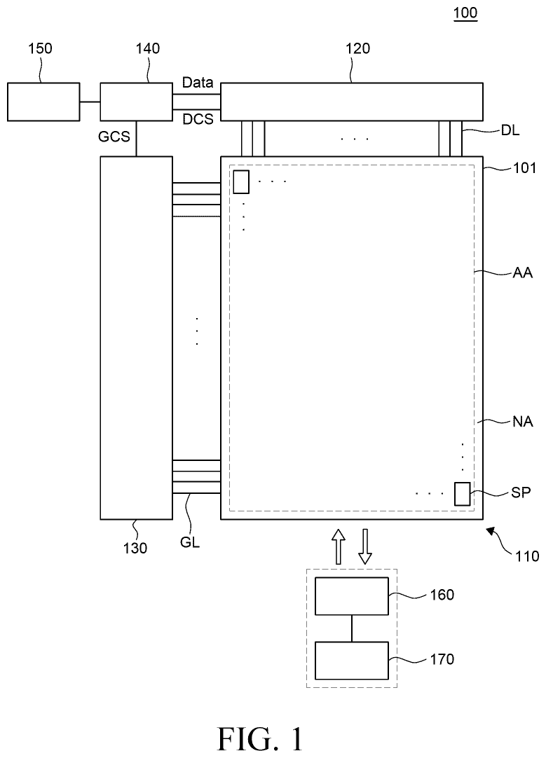

FIG. 1 is a system configuration diagram of a display device according to embodiments of the present disclosure.

Referring to FIG. 1, a display device 100 may include a display panel 110 and a display driving circuit as components for displaying an image.

The display driving circuit is a circuit for driving the display panel 110, and may include a data driving circuit 120, a gate driving circuit 130, a display controller 140, or the like.

The display panel 110 may include an active area AA where an image is displayed and a non-active area NA where an image is not displayed.

The non-active area NA may be an outer area of the active area AA, also called a bezel area. The entirety or part of the non-active area NA may be an area visible from the front of the display device 100, or may be an area that is bent and not visible from the front of the display device 100.

The display panel 110 may include a substrate 101 and a plurality of sub-pixels SP disposed on the substrate 101. In addition, the display panel 110 may further include various types of signal lines to drive the plurality of sub-pixels SP.

The display device 100 according to the embodiments of the present disclosure may be a liquid crystal display device or the like, or may be a light-emitting display device in which the display panel 110 emits light on its own. When the display device 100 according to the embodiments of the present disclosure is a self-emitting display device, each of the plurality of sub-pixels SP may include a light-emitting diode.

For example, the display device 100 according to the embodiments of the present disclosure may be an organic light-emitting display device in which the light-emitting diode is implemented as an organic light-emitting diode OLED.

For another example, the display device 100 according to embodiments of the present disclosure may be an inorganic light-emitting display device in which the light-emitting diode is implemented as an inorganic-based light-emitting diode. For another example, the display device 100 according to embodiments of the present disclosure may be a quantum dot display device in which the light-emitting diode is implemented as a quantum dot, which is a semiconductor crystal that emits light on its own.

Depending on the type of the display device 100, the structure of each of the plurality of sub-pixels SP may vary. For example, when the display device 100 is a self-luminous display device in which the sub-pixels SP emit light by themselves, each sub-pixel SP may include a light-emitting diode that emits light by itself, one or more transistors, and one or more capacitors.

For example, the various types of signal lines may include a plurality of data lines DL that carry data signals (also referred to as data voltages or image signals) and a plurality of gate lines GL that carry gate signals (also referred to as scan signals).

The plurality of data lines DL and the plurality of gate lines GL may intersect each other. Each of the plurality of data lines DL may be disposed to extend in a first direction. Each of the plurality of gate lines GL may be disposed to extend in a second direction.

Here, the first direction may be a column direction and the second direction may be a row direction. The first direction may be a row direction and the second direction may be a column direction.

The data driving circuit 120 is a circuit configured to drive the plurality of data lines DL and may output data signals to the plurality of data lines DL. The gate driving circuit 130 is a circuit configured to drive the plurality of gate lines GL and may output gate signals to the plurality of gate lines GL.

The display controller 140 may be a device configured to control the data driving circuit 120 and the gate driving circuit 130. The display controller 140 may control driving timing for the plurality of data lines DL and driving timing for the plurality of gate lines GL.

The display controller 140 may supply a data driving control signal DCS to the data driving circuit 120 to control the data driving circuit 120. The display controller 140 may supply a gate driving circuit control signal GCS to the gate driving circuit 130 to control the gate driving circuit 130.

The display controller 140 may receive input image data from a host system 150 and supply image data Data to the data driving circuit 120 based on the input image data.

The data driving circuit 120 may supply data signals to a plurality of data lines DL according to the drive timing control of the display controller 140.

The data driving circuit 120 may receive the image data Data in digital form from the display controller 140, convert the received image data Data into data signals in analog form, and output the converted data signal to the plurality of data lines DL.

The gate driving circuit 130 may supply gate signals to a plurality of gate lines GL according to the timing control of the display controller 140. The gate driving circuit 130 may receive a first gate voltage corresponding to a turn-on level voltage and a second gate voltage corresponding to a turn-off level voltage together with various gate driving circuit control signals GCS, generate gate signals, and supply the generated gate signals to a plurality of gate lines GL.

For example, the data driving circuit 120 may be connected to the display panel 110 by a tape automated bonding (TAB) method, connected to a bonding pad of the display panel 110 by a chip-on glass (COG) or chip-on panel (COP) method, or implemented by a chip-on film (COF) method and connected to the display panel 110.

The gate driving circuit 130 may be connected to the display panel 110 by the tape automated bonding (TAB) method, connected to a bonding pad of the display panel 110 by the chip-on-glass (COG) or chip-on-panel (COP) method, or connected to the display panel 110 by the chip-on-film (COF) method.

Alternatively, the gate driving circuit 130 may be formed in a non-active area NA of the display panel 110 as a gate-in-panel (GIP) type. The gate driving circuit 130 may be disposed on the substrate 101 or connected to the substrate 101.

That is, the gate driving circuit 130 may be disposed in a non-active area NA of the substrate 101 when the gate driving circuit 130 is a gate-in-panel (GIP) type. The gate driving circuit 130 may be connected to the substrate when the gate driving circuit 130 is the chip-on-glass (COG) type, a chip-on-film (COF) type, or the like.

Meanwhile, at least one of the data driving circuit 120 and the gate driving circuit 130 may be disposed in the active area AA of the display panel 110. For example, at least one of the data driving circuit 120 and the gate driving circuit 130 may be disposed so as not to overlap the sub-pixels SP, or may be disposed so as to partially or completely overlap the sub-pixels SP.

The data driving circuit 120 may be connected to one side (for example, the upper side or the lower side) of the display panel 110. Depending on the driving method, panel design method, or the like, the data driving circuit 120 may be connected to both sides (for example, the upper side and the lower side) of the display panel 110, or may be connected to two or more side surfaces among the four side surfaces of the display panel 110.

The gate driving circuit 130 may be connected to one side (for example, left or right) of the display panel 110. Depending on the driving method, panel design method, or the like, the gate driving circuit 130 may be connected to both sides (for example, left and right) of the display panel 110, or may be connected to two or more side surfaces of the four side surfaces of the display panel 110.

The display controller 140 may be implemented as a separate component from the data driving circuit 120, or may be implemented as an integrated circuit integrated with the data driving circuit 120.

The display controller 140 may be a timing controller used in conventional display technology, or may be a control device that may perform other control functions including a timing controller, or may be a control device other than the timing controller, or may be a circuit within the control device. The display controller 140 may be implemented with various circuits or electronic components such as an integrated circuit (IC), a field programmable gate array (FPGA), an application specific integrated circuit (ASIC), or a processor.

The display controller 140 may be electrically connected to the data driving circuit 120 and the gate driving circuit 130 through a printed circuit board (PCB), a flexible printed circuit board (FPCB), or the like.

The display controller 140 may transmit and receive signals to and from the data driving circuit 120 according to one or more predetermined interfaces. Here, for example, the interface may include a low voltage differential signaling (LVDS) interface, an EPI interface, a serial peripheral interface (SPI), or the like.

The display device 100 according to the embodiments of the present disclosure may include a touch sensor and a touch sensing circuit that senses the touch sensor to detect whether a touch has occurred by a touch object such as a finger or a pen, or to detect a touch position, in order to provide a touch sensing function in addition to an image display function.

The touch sensing circuit may include a touch driving circuit 160 that drives and senses a touch sensor to generate and output touch sensing data, a touch controller 170 that may detect a touch occurrence or a touch location using the touch sensing data, or the like.

The touch sensor may include a plurality of touch electrodes. The touch sensor may further include a plurality of touch lines for electrically connecting the plurality of touch electrodes and the touch driving circuit 160.

The touch sensor may be present in the form of a touch panel on the outside of the display panel 110 or may be present on the inside of the display panel 110.

When the touch sensor exists on the outside of the display panel 110 in the form of a panel, the touch sensor is referred to as external.

When the touch sensor is external, the touch panel and the display panel 110 may be manufactured separately and combined during the assembly process. The external touch panel may include a touch panel substrate, a plurality of touch electrodes on the touch panel substrate, or the like.

When the touch sensor is present inside the display panel 110, the touch sensor may be formed on the substrate 101 together with signal lines and electrodes related to display driving during the manufacturing process of the display panel 110.

The touch driving circuit 160 may supply a touch driving signal to at least one of a plurality of touch electrodes and generate touch sensing data by sensing at least one of the plurality of touch electrodes.

The touch sensing circuit may perform touch sensing using a self-capacitance sensing method or a mutual-capacitance sensing method.

When the touch sensing circuit performs touch sensing in a self-capacitance sensing manner, the touch sensing circuit may perform touch sensing based on the capacitance between each touch electrode and a touch object (for example, a finger, a pen, or the like).

According to the self-capacitance sensing method, each of the plurality of touch electrodes may function as both a driving touch electrode and a sensing touch electrode. The touch driving circuit 160 may drive all or some of the plurality of touch electrodes and sense all or some of the plurality of touch electrodes.

When the touch sensing circuit performs touch sensing in a mutual-capacitance sensing manner, the touch sensing circuit may perform the touch sensing based on the capacitance between touch electrodes.

According to the mutual-capacitance sensing method, the plurality of touch electrodes are divided into driving touch electrodes and sensing touch electrodes. The touch driving circuit 160 may drive the driving touch electrodes and sense the sensing touch electrodes.

The touch driving circuit 160 and the touch controller 170 included in the touch sensing circuit may be implemented as separate devices or as a single device. In addition, the touch driving circuit 160 and the data driving circuit 120 may be implemented as separate devices or as a single device.

The display device 100 may further include a power supply circuit that supplies various types of power to the display driving circuit and/or the touch sensing circuit, or the like.

The display device 100 according to the embodiments of the present disclosure may be a mobile terminal such as a smart phone or tablet, or a monitor or television (TV) of various sizes, but is not limited thereto. That is, the display device 100 may be a display device having various types and sizes capable of displaying information or images.

Below, for convenience of explanation, an example is given in which a touch panel TSP of the display device 100 according to the embodiments of the present disclosure is a built-in type.

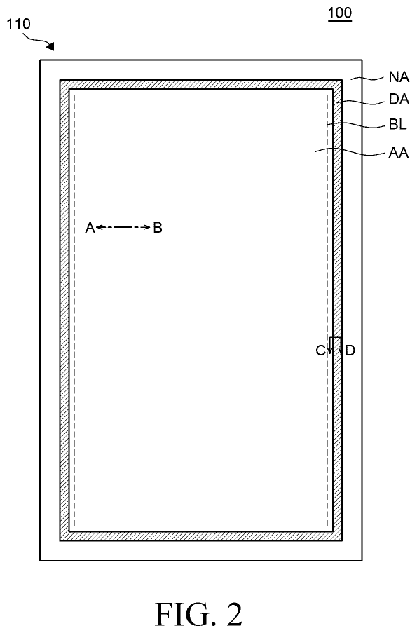

FIG. 2 is a schematic diagram of a display panel of a touch screen-integrated light-emitting display device according to embodiments of the present disclosure.

Referring to FIG. 2, the display panel 110 may include the active area AA where an image is displayed, and the non-active area NA which is an outer area of an outer boundary line BL of the active area AA.

In the active area AA of the display panel 110, a plurality of sub-pixels for image display are disposed, and various electrodes and signal lines for display driving are disposed.

Additionally, a plurality of touch electrodes for touch sensing and a plurality of touch routing wirings electrically connected thereto may be disposed in the active area AA of the display panel 110. Accordingly, the active area AA may also be referred to as a touch sensing area capable of touch sensing.

In the non-active area NA of the display panel 110, link lines through which various signal lines disposed in the active area AA are extended, or link lines electrically connected to various signal lines disposed in the active area AA, and pads electrically connected to these link lines may be disposed.

The display driving circuits (DDC, GDC, or the like) may be bonded or electrically connected to pads disposed in the non-active area NA.

Additionally, in the non-active area NA of the display panel 110, link lines through which a plurality of touch routing wirings disposed in the active area AA are extended, or link lines electrically connected to the plurality of touch routing wirings disposed in the active area AA, and pads electrically connected to the link lines may be disposed.

A touch driving circuit (TDC) may be bonded or electrically connected to the pads disposed in the non-active area NA.

In the non-active area NA, there may be an extended portion of a portion of the outermost touch electrode among the plurality of touch electrodes disposed in the active area AA. Moreover, one or more electrodes (touch electrodes) of the same material as the plurality of touch electrodes disposed in the active area AA may be further disposed in the non-active area NA.

That is, all of the plurality of touch electrodes disposed in the display panel 110 may exist within the active area AA. Alternatively, some (for example, the outermost touch electrode) of the plurality of touch electrodes disposed in the display panel 110 may exist in the non-active area NA, or some (for example, the outermost touch electrode) of the plurality of touch electrodes disposed on the display panel 110 may span the active area AA and the non-active area NA.

Meanwhile, referring to FIG. 2, the display panel 110 of the touch screen-integrated light-emitting display device according to the embodiments of the present disclosure may include the dam area DA in which a dam DAM is disposed to suppress collapse of any layer (for example, an encapsulation layer in an organic light emitting display panel) within the active area AA.

That is, the dam DAM may function to suppress overflow of an organic layer contained in an encapsulation layer ENCAP toward the periphery.

The dam area DA may be located at the boundary point between the active area AA and the non-active area NA, or at any point in the non-active area NA that is the outer area of the active area AA.

The dam disposed in the dam area DA may be disposed so as to surround all directions of the active area AA, or may be disposed only on the periphery of one or more portions of the active area AA, such as portions with a layer prone to collapse.

The dam disposed in the dam area DA may be a single connected pattern or may include two or more disconnected patterns.

Additionally, the dam area DA may have only one dam, two dams, or three or more dams.

When two dams are disposed in the dam area DA, a first dam and a second dam spaced apart from the first dam may be included. The second dam may be disposed further from the active area AA than the first dam.

Additionally, when three dams are disposed in the dam area DA, a first dam, a second dam spaced apart from the first dam, and a third dam spaced apart from the second dam may be included. The second dam may be disposed further from the active area AA than the first dam, and the third dam may be disposed further from the active area AA than the second dam.

Additionally, only the first dam may be disposed in one direction, while both the second and third dams may be disposed in the other direction.

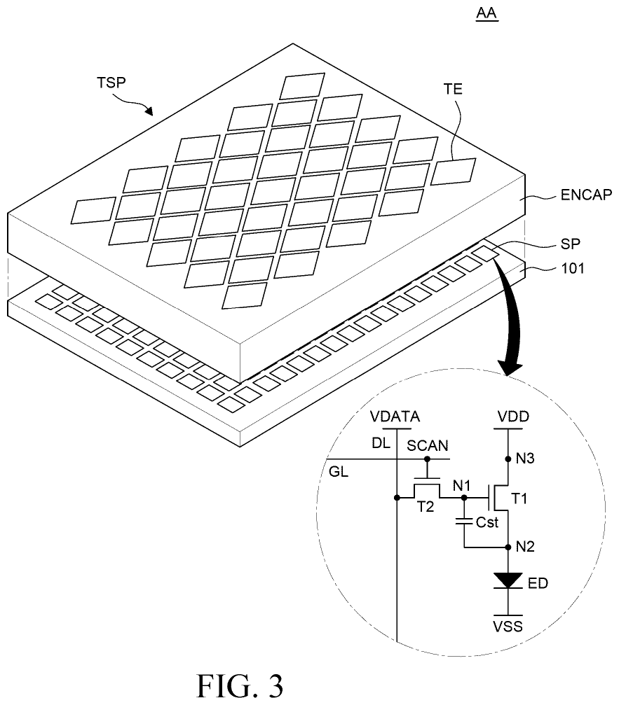

FIG. 3 is an exemplary drawing illustrating a structure in which a touch panel is embedded in the display panel according to embodiments of the present disclosure.

Referring to FIG. 3, in the active area AA of the display panel 110, the plurality of sub-pixels SP is disposed on the substrate 101.

Each sub-pixel SP may include a light-emitting diode ED, a first transistor T1 for driving the light-emitting diode ED, a second transistor T2 for transmitting a data voltage VDATA to a first node N1 of the first transistor T1, a storage capacitor Cst for maintaining a constant voltage for one frame, or the like.

The first transistor T1 may include the first node N1 to which the data voltage VDATA may be applied, a second node N2 electrically connected to the light-emitting diode ED, and a third node N3 to which a driving voltage VDD is applied from a driving voltage line.

The first node N1 may be a gate node, the second node N2 may be a source node or a drain node, and the third node N3 may be a drain node or a source node. This first transistor T1 is also referred to as a driving transistor that drives the light-emitting diode ED.

The light-emitting diode ED may include a first electrode (for example, an anode electrode), a light emitting layer, and a second electrode (for example, a cathode electrode).

The first electrode may be electrically connected to the second node N2 of the first transistor T1, and the second electrode may be applied with a base voltage VSS.

In the light-emitting diode ED, the light-emitting layer may be an organic light-emitting layer containing an organic material. In this case, the light-emitting diode ED may be an organic light-emitting diode OLED.

The second transistor T2 may be turned on and off by a scan signal SCAN applied through a gate line GL, and may be electrically connected between the first node N1 of the first transistor T1 and the data line DL. The second transistor T2 is also referred to as a switching transistor.

When the second transistor T2 is turned on by the scan signal SCAN, the second transistor T2 transmits the data voltage VDATA supplied from the data line DL to the first node N1 of the first transistor T1.

The storage capacitor Cst may be electrically connected between the first node N1 and the second node N2 of a first transistor T1.

Each sub-pixel SP may have a 2T1C structure including two transistors T1 and T2 and one capacitor Cst as illustrated in FIG. 3, and in some cases, may further include one or more transistors or one or more capacitors.

The storage capacitor Cst may be an external capacitor intentionally designed to the outside of the first transistor T1, not a parasitic capacitor (for example, Cgs, Cgd), which is an internal capacitor that may be present between the first node N1 and the second node N2 of the first transistor T1.

Each of the first transistor T1 and the second transistor T2 may be an n-type transistor or a p-type transistor.

Meanwhile, as described above, circuit elements such as a light-emitting diode ED, two or more transistors T1 and T2, and one or more capacitors Cst are disposed in the display panel 110.

Since these circuit elements (especially light-emitting diodes ED) are vulnerable to external moisture or oxygen, the encapsulation layer ENCAP may be disposed in the display panel 110 to suppress the penetration of the external moisture or oxygen into the circuit element (especially, light-emitting diode ED).

The encapsulation layer ENCAP may include a single layer or a plurality of layers.

Meanwhile, in the touch screen-integrated light-emitting display device according to the embodiments of the present disclosure, the touch panel TSP may be formed on the encapsulation layer ENCAP.

That is, in the touch-screen integrated light-emitting display device, a touch sensor structure such as a plurality of touch electrodes TE forming the touch panel TSP may be disposed on the encapsulation layer ENCAP.

During touch sensing, a touch driving signal or a touch sensing signal may be applied to the touch electrode TE.

Therefore, during the touch sensing, a potential difference may be formed between the touch electrode TE and the cathode electrode, which are disposed with the encapsulation layer ENCAP in between, and unnecessary parasitic capacitance may be formed.

The parasitic capacitance may reduce touch sensitivity. Therefore, in order to reduce the parasitic capacitance, the distance between the touch electrode TE and the cathode electrode may be designed to be equal to or more than a certain value in consideration of the panel thickness, panel manufacturing process, display performance, or the like.

Next, the structure of the active area AA and the non-active area NA of the display device according to one embodiment of the present disclosure will be specifically reviewed.

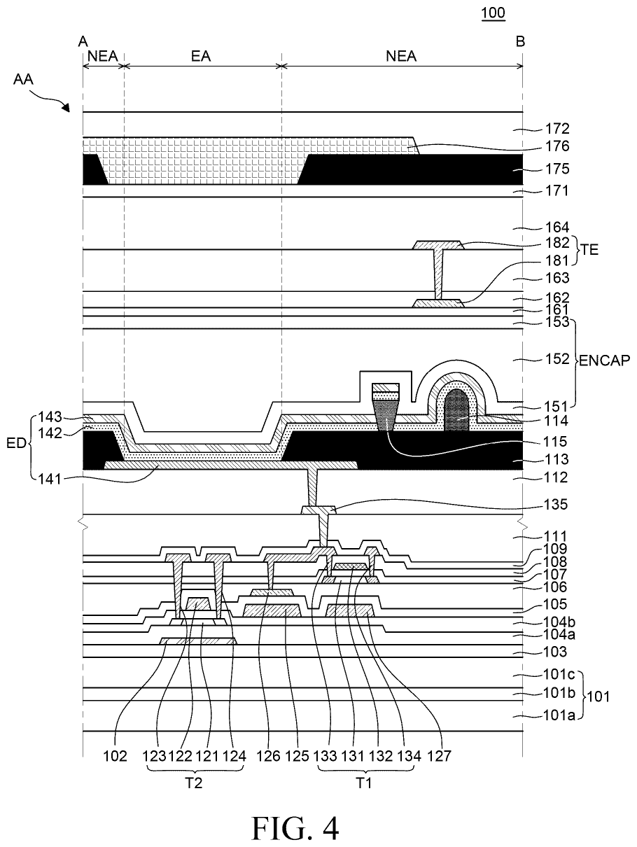

FIG. 4 is a cross-sectional view taken along line A-B of FIG. 2.

Referring to FIG. 4, the substrate 101 may include a first substrate 101a, an intermediate film 101b, and a second substrate 101c. The intermediate film 101b may be positioned between the first substrate 101a and the second substrate 101c. Since the substrate 101 includes the first substrate 101a, the intermediate film 101b, and the second substrate 101c, moisture penetration may be suppressed. For example, the first substrate 101a and the second substrate 101c may be polyimide (PI) substrates. The first substrate 101a may be referred to as a primary PI substrate, and the second substrate 101c may be referred to as a secondary PI substrate.

The first transistor T1, the second transistor T2, and storage capacitors 125 and 126 may be disposed on the second substrate 101c.

The second transistor T2 may include a first active layer 121, a first gate electrode 122, a first source electrode 123, and a first drain electrode 124.

The first transistor T1 may include a second active layer 131, a second gate electrode 132, a second source electrode 133, and a second drain electrode 134.

The storage capacitors 125 and 126 may include a first storage capacitor electrode 125 and a second storage capacitor electrode 126.

Specifically, a multi-buffer layer 103 may be disposed on the second substrate 101c, and a first active buffer layer 104a may be disposed on the multi-buffer layer 103.

A first metal layer 102 may be disposed on the first active buffer layer 104a. Here, the first metal layer 102 may be a light shield layer (LS) that blocks light.

A second active buffer layer 104b may be disposed on the first metal layer 102.

The first active layer 121 of the second transistor T2 may be disposed on the second active buffer layer 104b.

The first active layer 121 may be disposed to overlap the first metal layer 102.

A first gate insulating layer 105 may be disposed on the first active layer 121. The first gate insulating layer 105 may be disposed to cover the first active layer 121.

The first gate electrode 122 of the second transistor T2 may be disposed on the first gate insulating layer 105. The first gate electrode 122 may be disposed to overlap the first active layer 121.

Additionally, the first storage capacitor electrode 125 may be disposed on the first gate insulating layer 105.

The first storage capacitor electrode 125 may be disposed in an area different from the area where the first gate electrode 122 is disposed.

A first interlayer insulating layer 106 may be disposed on the first gate electrode 122 and the first storage capacitor electrode 125. The first interlayer insulating layer 106 may be disposed to cover the first gate electrode 122 and the first storage capacitor electrode 125.

The second storage capacitor electrode 126 and a second metal layer 127 may be disposed on the first interlayer insulating layer 106.

The second storage capacitor electrode 126 may be disposed to overlap the first storage capacitor electrode 125.

The second metal layer 127 may be disposed spaced apart from the second storage capacitor electrode 126. Here, the second metal layer 127 may be a light shield layer (LS) that blocks light.

A second interlayer insulating layer 107 may be disposed on the second storage capacitor electrode 126 and the second metal layer 127.

The second interlayer insulating layer 107 may be disposed to cover the second storage capacitor electrode 126 and the second metal layer 127.

The thickness of the second interlayer insulating layer 107 may be thicker than the thickness of the first interlayer insulating layer 106, but is not limited thereto.

The second active layer 131 of the first transistor T1 may be disposed on the second interlayer insulating layer 107.

Each of the first active layer 121 of the second transistor T2 and the second active layer 131 of the first transistor T1 may be formed of an oxide semiconductor, or may be formed of amorphous silicon (a-Si), polycrystalline silicon (poly-Si), an organic semiconductor, or the like.

The second active layer 131 may be disposed to overlap the second metal layer 127.

A second gate insulating layer 108 may be disposed on the second active layer 131. The second gate insulating layer 108 may be disposed to cover the second active layer 131.

The second gate electrode 132 of the first transistor T1 may be disposed on the second gate insulating layer 108. The second gate electrode 132 may be disposed to overlap the second active layer 131.

A third interlayer insulating layer 109 may be disposed on the second gate electrode 132.

The third interlayer insulating layer 109 may be disposed to cover the second gate electrode 132.

The first source electrode 123 and the first drain electrode 124 of the second transistor T2 may be spaced apart from each other on the third interlayer insulating layer 109. Moreover, the second source electrode 133 and the second drain electrode 134 of the first transistor T1 may be spaced apart from each other on the third interlayer insulating layer 109.

Meanwhile, the reference numeral 123 of the second transistor T2 is referred to as the first source electrode, and the reference numeral 124 is referred to as the first drain electrode, but this is not limited thereto. For example, the reference numeral 123 may be the first drain electrode of the second transistor T2, and the reference numeral 124 may be the first source electrode of the second transistor T2.

In addition, although the reference numeral 133 of the first transistor T1 is referred to as the second source electrode and the reference numeral 134 is referred to as the second drain electrode, this is not limited thereto. For example, the reference numeral 133 may be the second drain electrode of the first transistor T1, and the reference numeral 134 may be the second source electrode of the first transistor T1.

The first source electrode 123 and the first drain electrode 124 of the second transistor T2 may be electrically connected to one end and the other end of the first active layer 121 through contact holes provided in the third interlayer insulating layer 109, the second gate insulating layer 108, the second interlayer insulating layer 107, the first interlayer insulating layer 106, and the first gate insulating layer 105.

The portion of the first active layer 121 that overlaps the first gate electrode 122 is a channel region. The first source electrode 123 may be connected to one end of the channel region of the first active layer 121, and the first drain electrode 124 may be connected to the other end of the channel region of the first active layer 121.

The second source electrode 133 and the second drain electrode 134 of the first transistor T1 may be electrically connected to one end and the other end of the second active layer 131 through contact holes provided in the third interlayer insulating layer 109 and the second gate insulating layer 108.

The portion of the second active layer 131 that overlaps the second gate electrode 132 is a channel region. The second source electrode 133 may be connected to one end of the channel region of the second active layer 131, and the second drain electrode 134 may be connected to the other end of the channel region of the second active layer 131.

Additionally, the second source electrode 133 of the first transistor T1 may overlap the first storage capacitor electrode 125 and the second storage capacitor electrode 126.

The second source electrode 133 may be electrically connected to the second storage capacitor electrode 126 through contact holes provided in the third interlayer insulating layer 109, the second gate insulating layer 108, and the second interlayer insulating layer 107.

A first planarization layer 111 may be disposed on the first source electrode 123 and the first drain electrode 124 of the second transistor T2 and the second source electrode 133 and the second drain electrode 134 of the first transistor T1.

The first planarization layer 111 may serve to planarize the top surface of the substrate 101 on which the first source electrode 123 and the first drain electrode 124 of the second transistor T2 and the second source electrode 133 and the second drain electrode 134 of the first transistor T1 are disposed.

A connecting electrode 135 may be disposed on the first planarization layer 111.

The connecting electrode 135 may be electrically connected to the second source electrode 133 of the second transistor T1 through a contact hole provided in the first planarization layer 111.

A second planarization layer 112 may be disposed on the connecting electrode 135.

The second planarization layer 112 may serve to planarize the top surface of the substrate 101 on which the connecting electrode 135 is disposed.

The light-emitting diode ED may be disposed on the second planarization layer 112.

The light-emitting diode ED may include a first electrode 141, an organic layer 142, and a second electrode 143.

The first electrode 141 may be disposed on the second planarization layer 112.

The first electrode 141 may be electrically connected to the connecting electrode 135 through the contact hole of the second planarization layer 112.

A bank 113 may be disposed on a portion of the top surface of the first electrode 141 and on the second planarization layer 112.

The bank 113 may be disposed to cover a portion of the first electrode 141. The bank 113 may include a bank hole (or an opening of the bank) that exposes the top surface of the first electrode 141 in an emission area EA of the sub-pixel SP.

The organic layer 142 including at least one light-emitting layer may be disposed on the side surface of the bank 113 and in the hole of the bank 113.

That is, the organic layer 142 may be disposed on the top surface of the first electrode 141 exposed by the bank 113. Therefore, the organic layer 142 may come into contact with the top surface of the first electrode 141 in the hole of the bank 113.

The area where the bank 113 is disposed in the sub-pixel SP may correspond to a non-emission area NEA.

At least one spacer 114 may be disposed on the bank 113 in the non-emission area NEA.

In addition, in some cases, at least one reverse spacer 115 may be disposed on the bank 113 in the non-emission area NEA. The reverse spacer 115 may reduce unwanted leakage current between sub-pixels SP by disconnecting the organic layer 142 and the second electrode 143. Therefore, since color mixing is suppressed even at low brightness, deterioration of the image quality of the display device may be suppressed. In addition, when the display device 100 is bendable or foldable, the reverse spacer 115 may suppress the lifting of the encapsulation layer ENCAP disposed on the second electrode 143 due to the bending or folding.

The spacer 114 and the reverse spacer 115 may be formed integrally with the bank 113. However, this is not limited thereto, and the spacer 114 and the reverse spacer 115 may be formed through a process different from the process of forming the bank 113, so that a boundary may exist between the bank 113 and the spacer 114 and between the bank 113 and the reverse spacer 115.

The second electrode 143 may be disposed on the organic layer 142, bank 113, spacer 114, and reverse spacer 115.

The encapsulation layer ENCAP may be disposed on the second electrode 143.

The encapsulation layer ENCAP may have a single-layer structure or a multi-layer structure. For example, the encapsulation layer ENCAP may include a first encapsulation layer 151, a second encapsulation layer 152, and a third encapsulation layer 153.

The first encapsulation layer 151 and the third encapsulation layer 153 may be inorganic films, and the second encapsulation layer 152 may be an organic film. Among the first encapsulation layer 151, the second encapsulation layer 152, and the third encapsulation layer 153, the second encapsulation layer 152, which is an organic film, is the thickest and may function as a planarizing layer.

The first encapsulation layer 151 may be disposed on the cathode electrode (CE) and disposed closest to the light-emitting diode ED. The first encapsulation layer 151 may be formed of an inorganic insulating material capable of low-temperature deposition.

For example, the first encapsulation layer 151 may be silicon nitride (SiNₓ), silicon oxide (SiOₓ), silicon oxynitride (SiON), or aluminum oxide (Al₂O₃). Since the first encapsulation layer 151 is deposited in a low-temperature atmosphere, the first encapsulation layer 151 may suppress the damage to the light-emitting layer (EL) containing an organic material that is vulnerable to a high-temperature atmosphere during the deposition process.

The second encapsulation layer 152 may be formed with a smaller area than the first encapsulation layer 151. In this case, the second encapsulation layer 152 may be formed to expose both ends of the first encapsulation layer 151.

The second encapsulation layer 152 acts as a buffer to alleviate stress between layers due to bending of the display device 100, and may also serve to enhance flattening performance.

For example, the second encapsulation layer 152 may be formed of an organic insulating material, such as acrylic resin, epoxy resin, polyimide, polyethylene, or silicon oxycarbon (SiOC). For example, the second encapsulation layer 152 may be formed using an inkjet method.

The second encapsulation layer 152, also called a particle cover layer (PCL), has an excellent flattening function. Therefore, the second encapsulation layer 152 may compensate for the step difference of the lower layer and is suitable for providing a flattening function.

The third encapsulation layer 153 may be formed on the substrate 101 on which the second encapsulation layer 152 may be formed to cover the top surface and side surface of each of the second encapsulation layer 152 and the first encapsulation layer 151.

The third encapsulation layer 153 may minimize or block external moisture or oxygen from penetrating into the first encapsulation layer 151 and the second encapsulation layer 152. For example, the third encapsulation layer 153 may be formed of an inorganic insulating material such as silicon nitride (SiNₓ), silicon oxide (SiOₓ), silicon oxynitride (SiON), or aluminum oxide (Al₂O₃).

A touch electrode TE may be disposed on the encapsulation layer ENCAP. The touch electrode TE may include a first touch electrode 181 and a second touch electrode 182.

The first touch electrode 181 and the second touch electrode 182 may be disposed on different layers. The structure of the touch electrode TE is described in detail as follows.

A first touch buffer layer 161 may be disposed on the encapsulation layer ENCAP.

The first touch electrode 181 may be disposed on the first touch buffer layer 161. Here, the first touch electrode 181 may also be referred to as a bridge electrode.

A second touch buffer layer 162 may be disposed on the first touch electrode 181.

The second touch buffer layer 162 may be disposed to cover the first touch electrode 181.

The second touch buffer layer 162 may include an inorganic insulating material. For example, the second touch buffer layer 162 may be composed of a single layer of silicon nitride (SiNₓ) or silicon oxide (SiOₓ), or a multilayer of silicon nitride (SiNₓ) or silicon oxide (SiOₓ), but is not limited thereto.

A touch interlayer insulating layer 163 may be disposed on the second touch buffer layer 162.

The second touch electrode 182 may be disposed on the touch interlayer insulating layer 163. The second touch electrode 182 may be electrically connected to the first touch electrode 181 through contact holes provided in the second touch buffer layer 162 and the touch interlayer insulating layer 163.

The first touch electrode 181 and the second touch electrode 182 may be disposed in a non-emission area NEA of the sub-pixel SP. That is, the first touch electrode 181 and the second touch electrode 182 may be disposed to overlap the bank 113.

Meanwhile, when the touch electrode TE is formed on the display panel 110, a chemical solution (developing solution or etching solution, or the like) used in the process may flow into the inside, or moisture may flow in from the outside.

By disposing the touch electrode TE on the first touch buffer layer 161, it is possible to suppress the penetration of chemicals or moisture into the organic layer 142 including the light-emitting layer during the manufacturing process of the touch electrode TE. Accordingly, the first touch buffer layer 161 may suppress the damage to the organic layer 142 which is vulnerable to chemicals or moisture.

The first touch buffer layer 161 may be formed at a low temperature, below a certain temperature (for example, 100 C) to suppress the damage to the organic layer 142 that is vulnerable to high temperatures, and formed of an organic insulating material having a low dielectric constant of 1 to 3, but is not limited thereto.

In addition, the second touch buffer layer 162 may be disposed between the first touch electrode 181 and the second touch electrode 182, and may serve to separate the first touch electrode 181 and the second touch electrode 182. The second touch buffer layer 162 may include at least one contact hole, and the first touch electrode 181 and the second touch electrode 182 may be connected through the contact hole provided in the second touch buffer layer 162.

The touch interlayer insulating layer 163 may include an organic insulating material. For example, the touch interlayer insulating layer 163 may include an acrylic series, epoxy series, or siloxane series material.

Meanwhile, as the display device 100 is bent, the encapsulation layer ENCAP may be damaged and the touch electrode TE positioned on the touch interlayer insulating layer 163 may be broken. Even when the display device 100 is bent, the touch interlayer insulating layer 163 having planarization performance including an organic insulating material may suppress the damage to the encapsulation layer ENCAP and/or breakage of the first touch electrode 181 and the second touch electrode 182 constituting the touch electrode TE.

In addition, the touch interlayer insulating layer 163 may play a role in reducing signal interference by lowering the dielectric constant between the touch electrode TE and various electrodes and wiring disposed under the touch electrode TE. Accordingly, the touch interlayer insulating layer 163 may play a role in improving the performance of the touch electrode TE.

A protective layer 164 may be disposed on the second touch electrode 182. The protective layer 164 may be disposed to cover the second touch electrode 182.

The protective layer 164 may be an organic insulating layer. The organic insulating layer may, for example, include the same material as the first planarization layer 111 and the second planarization layer 112 described above. In addition, the organic insulating layer may be formed of a different material from the second encapsulation layer 152. For example, the protective layer 164 may include a thermosetting resin.

A color buffer layer 171 may be disposed on the protective layer 164.

A black matrix 175 may be disposed on the color buffer layer 171. The black matrix 175 may be disposed to overlap a portion of the non-emission area NEA of the sub-pixel SP. In addition, the black matrix 175 may include an opening that exposes the emission area EA of the sub-pixel SP and a portion of the non-emission area NEA surrounding a portion of the emission area EA.

A color filter 176 may be disposed on a portion of the top surface of the black matrix 175 and on the color buffer layer 171.

The color filter 176 may be disposed in the emission area EA of the sub-pixel SP, and may also be disposed in a portion of the non-emission area NEA. This color filter 176 may be disposed within an opening of the black matrix 175, and may be disposed to cover the edge of the black matrix 175.

Additionally, the black matrix 175 may overlap the first touch electrode 181 and the second touch electrode 182.

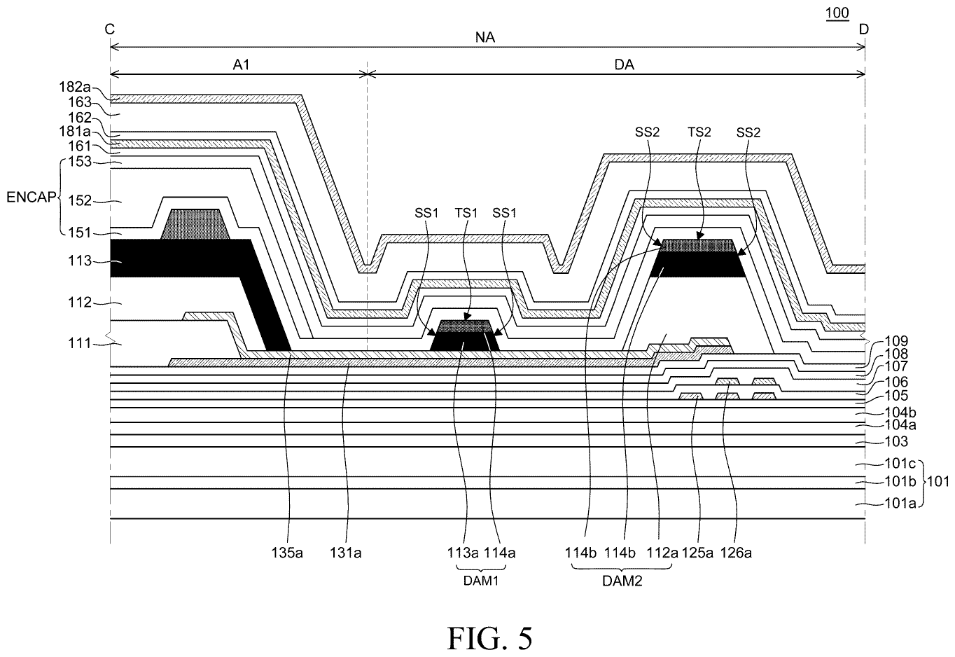

FIG. 5 is a cross-sectional view taken along line C-D of FIG. 2.

FIG. 5 is a drawing illustrating a portion of a non-active area NA including the dam area DA and an additional area A1 in the display panel 110 according to one embodiment of the present disclosure.

Referring to FIG. 5, the non-active area NA may include the dam area DA in which at least one of dams DAM1 and DAM2 is disposed.

Additionally, the non-active area NA may include the additional area A1 positioned between the active area AA and the dam area DA.

Specifically, the multi-buffer layer 103, the first active buffer layer 104a, the second active buffer layer 104b, the first gate insulating layer 105, the first interlayer insulating layer 106, the second interlayer insulating layer 107, the second gate insulating layer 108, and the third interlayer insulating layer 109 disposed on the substrate 101 may be disposed in the non-active area NA of the display panel 110.

Each of the multi-buffer layer 103, the first active buffer layer 104a, the second active buffer layer 104b, the first gate insulating layer 105, the first interlayer insulating layer 106, the second interlayer insulating layer 107, the second gate insulating layer 108, and the third interlayer insulating layer 109 may be disposed to extend from the active area AA to the non-active area NA.

A plurality of first wirings 125a may be disposed on the first gate insulating layer 105 in the non-active area NA. The plurality of first wirings 125a may be disposed on the same layer as the first gate electrode 122 and the first storage capacitor electrode 125 in the active area AA.

Additionally, a plurality of second wirings 126a may be disposed on the first interlayer insulating layer 106 in the non-active area NA. The plurality of second wirings 126a may be disposed on the same layer as the second storage capacitor electrode 126 and the second metal layer 127 in the active area AA.

The plurality of first wirings 125a and the plurality of second wirings 126a may be detection wirings that detect cracks in the display panel 110.

A first base wiring 131a may be disposed on the third interlayer insulating layer 109 in the non-active area NA. The first base wiring 131a may be disposed on the same layer as the first source electrode 123, the first drain electrode 124, the second source electrode 133, and the second drain electrode 134 in the active area AA.

The first planarization layer 111 may be disposed on a portion of the top surface of the first base wiring 131a and on the third interlayer insulating layer 109. The first planarization layer 111 may be disposed to extend from the active area AA.

The first planarization layer 111 may be disposed to expose a portion of the top surface of the first base wiring 131a.

A second base wiring 135a may be disposed on the first planarization layer 111 and the first base wiring 131a. The second base wiring 135a may be disposed on the same layer as the connecting electrode 135 in the active area AA.

The first base wiring 131a and the second base wiring 135a disposed in the non-active area NA may be low-potential voltage wirings or connection wirings (or connecting electrodes) connected to low-potential voltage wirings.

The second planarization layer 112 may be disposed on a portion of the top surface of the second base wiring 135a and on the first planarization layer 111.

The second planarization layer 112 may be disposed to cover at least a portion of the edge of the second base wiring 135a. The second planarization layer 112 may be disposed to extend from the active area AA to at least a portion of the non-active area NA.

Specifically, the second planarization layer 112 may cover the first planarization layer 111 and the second base wiring 135a disposed on the first planarization layer 111. The second planarization layer 112 may also be disposed on a portion of the top surface of the second base wiring 135a that is in contact with the first base wiring 131a.

Additionally, the second planarization layer pattern 112a disposed on the same layer as the second planarization layer 112 may be disposed to cover one end of each of the first base wiring 131a and the second base wiring 135a that do not overlap the first planarization layer 111.

The second planarization layer pattern 112a may also be disposed on a portion of the top surface of the third interlayer insulating layer 109.

The bank 113 may be disposed on the second planarization layer 112 in the non-active area NA. The bank 113 may be disposed to extend from the active area AA to at least a portion of the non-active area NA.

The bank 113 may be disposed to cover the second planarization layer 112 disposed in the non-active area NA. The bank 113 may also be disposed on a portion of the top surface of the second base wiring 135a.

Additionally, a first bank pattern 113a and a second bank pattern 113b prepared through the same process as the bank 113 may be disposed in the non-active area NA.

The first bank pattern 113a may be disposed on the top surface of the second base wiring 135a.

A first spacer pattern 114a may be disposed on the first bank pattern 113a.

The first bank pattern 113a and the first spacer pattern 114a disposed on the first bank pattern 113a may constitute the first dam DAM1. In other words, the first dam DAM1 may include the first bank pattern 113a and the first spacer pattern 114a disposed on the first bank pattern 113a.

The second bank pattern 113b may be disposed on the second planarization layer pattern 112a.

The second spacer pattern 114b may be disposed on the second bank pattern 113b.

The second planarization layer pattern 112a, the second bank pattern 113b disposed on the second planarization layer pattern 112a, and the second spacer pattern 114b disposed on the second bank pattern 113b may form the second dam DAM2.

In other words, the second dam DAM2 may include the second planarization layer pattern 112a, the second bank pattern 113b disposed on the second planarization layer pattern 112a, and the second spacer pattern 114b disposed on the second bank pattern 113b.

Meanwhile, in FIG. 5, the first dam DAM1 is illustrated as having a structure including the first bank pattern 113a and the first spacer pattern 114a disposed on the first bank pattern 113a, but is not limited thereto. For example, the first bank pattern 113a and the first spacer pattern 114a may be formed integrally.

In addition, although the second dam DAM2 is illustrated as having a structure including the second bank pattern 113b and the second spacer pattern 114b disposed on the second bank pattern 113b, but is not limited thereto. For example, the second bank pattern 113b and the second spacer pattern 114b may be formed integrally.

The first dam DAM1 and the second dam DAM2 may function to suppress the overflowing of the material of the second encapsulation layer 152, which is included in the encapsulation layer ENCAP, toward the outside.

The height of the second dam DAM2 may be higher than the height of the first dam DAM1. Accordingly, even when the first dam DAM1 may not suppress the overflowing of the material of the second encapsulation layer 152, the second dam DAM2 may suppress the overflowing of the material of the second encapsulation layer 152.

In addition, the second dam DAM2 may be disposed to surround at least one end of each of the first base wiring 131a and the second base wiring 135a, thereby protecting at least one end of each of the first base wiring 131a and the second base wiring 135a.

The first encapsulation layer 151 may be disposed on a substrate 101 on which a first dam DAM1 and a second dam DAM2 are disposed in a non-active area NA.

The first encapsulation layer 151 may be disposed to extend from the active area AA to at least a portion of the non-active area NA. The first encapsulation layer 151 may be disposed to cover the bank 113, the second base wiring 135a, the first dam DAM1, the second dam DAM2, and the third interlayer insulating layer 109.

In other words, the first encapsulation layer 151 may be disposed on the side surface SS1 and top surface TS1 of the first dam DAM1 and may be disposed on the side surface SS2 and top surface TS2 of the second dam DAM2.

The second encapsulation layer 152 may be disposed on a portion of the top surface of the first encapsulation layer 151.

The second encapsulation layer 152 may be disposed to extend from the active area AA and may extend to the area between the bank 113 and the first dam DAM1.

Meanwhile, the second encapsulation layer 152 is illustrated as having a structure in which the second encapsulation layer 152 is disposed to be spaced apart from the first encapsulation layer 151 disposed on the side surface of the first dam DAM1, but is not limited thereto. For example, the second encapsulation layer 152 may be disposed to be in contact with at least a portion of the first encapsulation layer 151 disposed on the side surface of the first dam DAM1.

In this way, the second encapsulation layer 152 may not be disposed beyond the non-active area NA by the first dam DAM1.

The third encapsulation layer 153 may be disposed on the second encapsulation layer 152 and the first encapsulation layer 151.

The third encapsulation layer 153 may be disposed to extend from the active area AA and disposed to at least a portion of the non-active area NA.

The third encapsulation layer 153 may be disposed to cover the second encapsulation layer 152. In addition, the third encapsulation layer 153 may also be disposed on the first encapsulation layer 151 that does not overlap the second encapsulation layer 152 in the non-active area NA.

The third encapsulation layer 153 may be disposed on the first encapsulation layer 151 disposed on the side surface and top surface of the first dam DAM1, and may be disposed on the first encapsulation layer 151 disposed on the side surface and top surface of the second dam DAM2.

The first touch buffer layer 161 may be disposed on the third encapsulation layer 153 in the non-active area NA.

The first touch buffer layer 161 may be disposed to extend from the active area AA and disposed to at least a portion of the non-active area NA.

The first touch buffer layer 161 may be disposed to overlap the first encapsulation layer 151 and the third encapsulation layer 153 disposed on the side surface and top surface of the first dam DAM1. Moreover, the first touch buffer layer 161 may be disposed to overlap the first encapsulation layer 151 and the third encapsulation layer 153 disposed on the side surface and top surface of the second dam DAM2.

A first touch electrode line 181a may be disposed on the first touch buffer layer 161.

The first touch electrode line 181a may be a line connected to the first touch electrode 181 disposed in the active area AA.

The first touch electrode line 181a may include the same material as the first touch electrode 181.

The first touch electrode line 181a may be disposed to overlap the first encapsulation layer 151, the third encapsulation layer 153, and the first touch buffer layer 161 disposed on the side surface and top surface of the first dam DAM1. Moreover, the first touch electrode line 181a may be disposed to overlap the first encapsulation layer 151, the third encapsulation layer 153, and the first touch buffer layer 161 disposed on the side surface and top surface of the second dam DAM2.

The second touch buffer layer 162 may be disposed on the first touch electrode line 181a.

The second touch buffer layer 162 may be disposed to extend from the active area AA and disposed to at least a portion of the non-active area NA.

The second touch buffer layer 162 may be disposed on the first encapsulation layer 151, the third encapsulation layer 153, the first touch buffer layer 161, and the first touch electrode line 181a disposed on the side surface and top surface of the first dam DAM1.

Additionally, the second touch buffer layer 162 may be disposed on the first encapsulation layer 151, the third encapsulation layer 153, the first touch buffer layer 161, and the first touch electrode line 181a disposed on the side surface and top surface of the second dam DAM2.

The touch interlayer insulating layer 163 may be disposed on the top surface of the second touch buffer layer 162 in the non-active area NA.

A portion of the touch interlayer insulating layer 163 may be disposed to overlap the top surface and side surfaces of the second encapsulation layer 152 disposed in the non-active area NA. Specifically, a portion of the touch interlayer insulating layer 163 may be disposed to extend from the active area AA and disposed to the area between the second encapsulation layer 152 disposed in the non-active area NA and the first dam DAM1.

Additionally, a portion of the touch interlayer insulating layer 163 may be disposed to overlap the first encapsulation layer 151, the third encapsulation layer 153, the first touch buffer layer 161, the first touch electrode line 181a, and the second touch buffer layer 162 disposed on the top surface and side surfaces of the first dam DAM1.

Additionally, another portion of the touch interlayer insulating layer 163 may be disposed to overlap the first encapsulation layer 151, the third encapsulation layer 153, the first touch buffer layer 161, the first touch electrode line 181a, and the second touch buffer layer 162 disposed to overlap the top surface and side surfaces of the second dam DAM2.

The touch interlayer insulating layer 163 may be positioned to expose a portion of the top surface of the second touch buffer film 162 in the non-active area NA, but is not limited thereto.

A second touch electrode line 182a may be disposed on the touch interlayer insulating layer 163.

The second touch electrode line 182a may be a line connected to the second touch electrode 182 disposed in the active area AA.

The second touch electrode line 182a may include the same material as the second touch electrode 182.

The second touch electrode line 182a may be disposed on the first encapsulation layer 151, the third encapsulation layer 153, the first touch buffer layer 161, the first touch electrode line 181a, the second touch buffer layer 162, and the touch interlayer insulating layer 163 disposed on the side surface and top surface of the first dam DAM1.

In addition, the second touch electrode line 182a may be disposed to overlap the first encapsulation layer 151, the third encapsulation layer 153, the first touch buffer layer 161, the first touch electrode line 181a, the second touch buffer layer 162, and the touch interlayer insulating layer 163 disposed on the side surface and top surface of the second dam DAM2.

That is, the first encapsulation layer 151, the third encapsulation layer 153, the first touch buffer layer 161, the first touch electrode line 181a, the second touch buffer layer 162, the touch interlayer insulating layer 163, and the second touch electrode line 182a may be sequentially laminated on the surface of the first dam DAM1.

Additionally, the first encapsulation layer 151, the third encapsulation layer 153, the first touch buffer layer 161, the first touch electrode line 181a, the second touch buffer layer 162, the touch interlayer insulating layer 163, and the second touch electrode line 182a may be sequentially laminated on the surface of the second dam DAM2.

Meanwhile, the display device 100 including the plurality of touch electrodes TE or the color filter 176 has a problem in that damage is applied to the remaining components in the process of patterning various insulating layers, electrodes or wirings. Therefore, a gap is generated, a moisture penetration path is generated, and a defect in the light-emitting diode ED is caused.

Specifically, in the process of forming the first touch electrode 181 and the first touch electrode line 181a, the process of forming the second touch buffer layer 162, or the process of forming the second touch electrode 182 and the second touch electrode line 182a, at least one of the first encapsulation layer 151 and the third encapsulation layer 153 disposed on the first dam DAM1 or the second dam DAM2 is damaged.

Accordingly, a moisture permeation path is generated due to the damage in the first encapsulation layer 151 and the third encapsulation layer 153, and the light-emitting diode ED disposed in the active area AA has a problem in that the lifespan is reduced due to the influence of moisture permeation.

The display device 100 according to one embodiment of the present disclosure may include the first touch electrode line 181a that overlaps the first dam DAM1 and the second dam DAM2 so that a defect does not occur in the first encapsulation layer 151 and the third encapsulation layer 153 in the process of forming the first touch electrode 181 and the first touch electrode line 181a and the process of forming the second touch buffer layer 162.

When the first touch electrode line 181a is not disposed on the first dam DAM1 and the second dam DAM2, the plasma or wet etching solution may cause damage to the first encapsulation layer 151 and the third encapsulation layer 153 in the process of forming the first touch electrode 181 and the first touch electrode line 181a and the process of forming the second touch buffer layer 162.

In addition, the display device 100 according to one embodiment of the present disclosure may include the second touch electrode line 182a on the first dam DAM1 and the second dam DAM2 so that a defect does not occur in the first encapsulation layer 151 and the third encapsulation layer 153 in the process of forming the second touch electrode 182 and the second touch electrode line 182a, and may include the second touch buffer layer 162 and the touch interlayer insulating layer 163 overlapping the first dam DAM1 and the second dam DAM2.

When the first touch electrode line 181a is not disposed on the first dam DAM1 and the second dam DAM2, the plasma or wet etching solution may cause damage to the first encapsulation layer 151 and the third encapsulation layer 153 during the process of forming the second touch electrode 182 and the second touch electrode line 182a.

In addition, the second touch buffer layer 162 and the touch interlayer insulating layer 163 are disposed between the first dam DAM1 and the second dam DAM2 with the second touch electrode line 182a. By disposing the second touch buffer layer 162 and the touch interlayer insulating layer 163 between the first dam DAM1 and the second dam DAM2 with the second touch electrode line 182a, it is possible to additionally suppress the damage to the first encapsulation layer 151 and the third encapsulation layer 153 due to plasma or a wet etching solution in the process of forming the second touch electrode 182 and the second touch electrode line 182a.

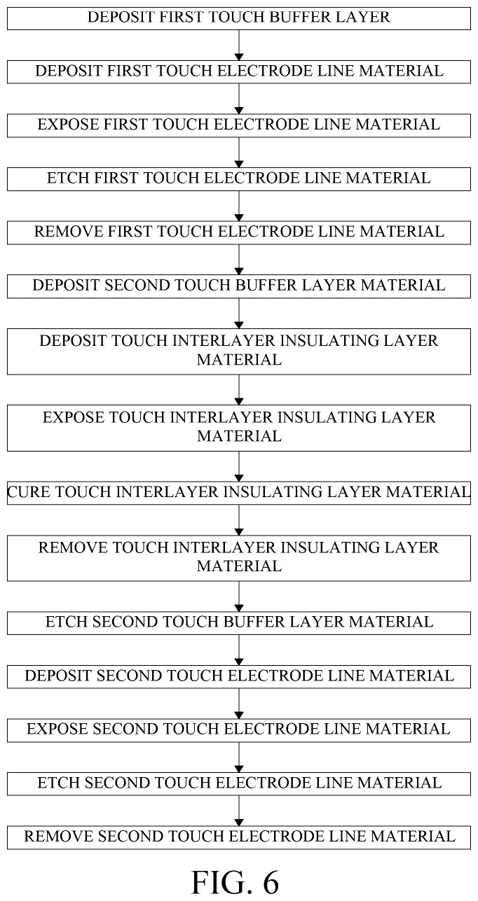

Next, referring to FIG. 6, the process of forming the components disposed on the encapsulation layer ENCAP disposed in the non-active area NA is specifically examined as follows.

FIG. 6 is a drawing illustrating the process sequence for forming components disposed on the encapsulation layer in the non-active area.

Referring to FIG. 6, the first touch buffer layer 161 may be deposited on the third encapsulation layer 153 in the non-active area NA.

After this, a first touch electrode line material may be deposited on the first touch buffer layer 161. Using the first touch electrode line material, the first touch electrode line 181a disposed in the non-active area NA and the first touch electrode 181 disposed in the active area AA may be formed. However, the following description will focus on the process of forming the first touch electrode line 181a disposed in the non-active area NA.

Specifically, a photoresist may be formed on the first touch electrode line material.

Thereafter, the photoresist disposed on the first touch electrode line material may be patterned through an exposure process using a mask.

The first touch electrode line material may be etched using the patterned photoresist as a mask. In this case, a dry etching process using plasma may be utilized to etch the first touch electrode line material.

Afterwards, the first touch electrode line material in the area where the photoresist is not disposed may be removed to form the first touch electrode line 181a in the non-active area NA.

During the process of forming the first touch electrode line 181a, the dry etching process using plasma may cause damage to the first encapsulation layer 151, the third encapsulation layer 153, and the first touch buffer layer 161, which are components disposed under the first touch electrode line 181a.

In this case, gaps may occur in the first encapsulation layer 151 and the third encapsulation layer 153, which serve to suppress the penetration of moisture into the plurality of light-emitting diodes ED disposed in the active area AA of the display panel 110.

The gaps formed in the first encapsulation layer 151 and the third encapsulation layer 153 may act as a path for moisture or oxygen to penetrate. Therefore, moisture or oxygen penetrated from the non-active area NA may reach the light-emitting diode ED disposed in the active area AA.

Accordingly, the lifespan of the light-emitting diode ED may be reduced and the reliability of the display panel 110 may be reduced.

Specifically, the second encapsulation layer 152 among the encapsulation layer ENCAP that suppress the penetration of the moisture or oxygen into the light-emitting diode ED may not be disposed in at least a part of the dam area DA in which at least one dam is disposed in the non-active area NA.

For example, as illustrated in FIG. 5, the second encapsulation layer 152 may not be disposed on the first dam DAM1 and the second dam DAM2. Therefore, in the dam area DA of the non-active area NA, the penetration of moisture and oxygen should be suppressed only by the first encapsulation layer 151 and the third encapsulation layer 153. Therefore, the damage to the first encapsulation layer 151 and the third encapsulation layer 153 should be suppressed.

Meanwhile, in the non-active area NA, in the area where the first touch electrode line 181a is not disposed, there is no photoresist to block plasma in the dry etching process. Accordingly, in the area where the first touch electrode line 181a is not disposed, the damage to the first encapsulation layer 151, the third encapsulation layer 153, and the first touch buffer layer 161 may occur.

In addition, when the first touch electrode line material for forming the first touch electrode line 181a is excessively etched, the probability of damage to the first encapsulation layer 151, the third encapsulation layer 153, and the first touch buffer layer 161 may further increase.

However, in the display device 100 according to one embodiment of the present disclosure, the first touch electrode line 181a is disposed on the first encapsulation layer 151, the third encapsulation layer 153, and the first touch buffer layer 161 disposed on the first dam DAM1 and the second dam DAM2. Accordingly, it is possible to suppress the damage to the first encapsulation layer 151, the third encapsulation layer 153, and the first touch buffer layer 161 in the process of forming the first touch electrode line 181a.

In particular, since the photoresist disposed on the first touch electrode line 181a acts to block plasma in the dry etching process of forming the first touch electrode line 181a, the components disposed under the first touch electrode line 181a are not affected by plasma. Accordingly, it is possible to suppress the damage to the first encapsulation layer 151, the third encapsulation layer 153, and the first touch buffer layer 161 to extend the lifespan of the light-emitting diode ED.

In this way, by improving the lifespan of the light-emitting diode ED included in the display device 100 including a plurality of touch electrodes TE, the display device 100 with improved reliability and low power operation may be provided.

Referring to FIG. 6, the second touch buffer layer material may be formed on the substrate 101 on which the first touch electrode line 181a is formed.

The second touch buffer layer material may include an inorganic insulating material.

Afterwards, the touch interlayer insulating layer material may be formed on the second touch buffer layer material.

The touch interlayer insulating material may include an organic insulating material.

A photoresist may be formed on the touch interlayer insulating layer material.

Afterwards, the photoresist disposed on the touch interlayer insulating layer material may be patterned through an exposure process using a mask.

The patterned photoresist may be used as a mask to cure the touch interlayer insulating layer material.

After the touch interlayer insulating layer material has been cured, the photoresist may be removed.

Afterwards, the portion of the touch interlayer insulating layer material that is not cured may be removed, and the portion that is not removed may become the touch interlayer insulating layer 163.

Thereafter, the second touch buffer layer material may be etched using the touch interlayer insulating layer 163 as a mask. A dry etching process using plasma may be utilized to etch the second touch buffer layer material.

Thereafter, the second touch buffer layer material in the area where the touch interlayer insulating layer 163 is not disposed may be removed, and the second touch buffer layer material that is not removed may become the second touch buffer layer 162.

During the process of forming the second touch buffer layer 162, in the dry etching process using plasma, gaps are generated in the first encapsulation layer 151, the third encapsulation layer 153, and the first touch buffer layer 161, which are components disposed under the second touch buffer layer 162. Therefore, a path for moisture or oxygen to penetrate into the light-emitting diode ED disposed in the active area AA may be generated.

In this case, a problem may arise in which power consumption increases as the lifespan of the light-emitting diode ED decreases.

However, in the display device 100 according to one embodiment of the present disclosure, in the process of forming the second touch buffer layer 162, the first touch electrode line 181a may suppress the plasma's influence on the first encapsulation layer 151, the third encapsulation layer 153, and the first touch buffer layer 161 which are disposed below the first touch electrode line 181a.

Accordingly, the reliability of the first encapsulation layer 151, the third encapsulation layer 153, and the first touch buffer layer 161 disposed in the dam area DA of the non-active area NA is improved. Moreover, it is possible to suppress the reduction in the lifespan of the light-emitting diode ED disposed in the active area AA due to moisture penetration.

The second touch electrode line material may be deposited on the touch interlayer insulating layer 163. Using the second touch electrode line material, the second touch electrode line 182a disposed in the non-active area NA and the second touch electrode 182 disposed in the active area AA may be formed. However, the following description will focus on the process of forming the second touch electrode line 182a disposed in the non-active area NA.

A photoresist may be formed on the second touch electrode line material.

Thereafter, the photoresist disposed on the second touch electrode line material may be patterned through an exposure process using a mask.

The second touch electrode line material may be etched using the patterned photoresist as a mask. In this case, a dry etching process using plasma may be utilized to etch the second touch electrode line material.

Afterwards, the second touch electrode line material in the area where the photoresist is not disposed may be removed to form the second touch electrode line 182a in the non-active area NA.

During the process of forming the second touch electrode line 182a, the dry etching process using plasma may cause damage to the first encapsulation layer 151, the third encapsulation layer 153, and the first touch buffer layer 161, which are components disposed under the second touch electrode line 182a.

In particular, when the touch interlayer insulating layer 163 and the second touch buffer layer 162 disposed under the second touch electrode line 182a are not disposed, damage to the insulating layers disposed under the second touch electrode line 182a may occur.

However, in the display device 100 according to one embodiment of the present disclosure, the second touch buffer layer 162 and the touch interlayer insulating layer 163 are disposed between the second touch electrode line 182a and the first dam DAM1 and between the second touch electrode line 182a and the second dam DAM2. Accordingly, it is possible to suppress damage to the first encapsulation layer 151, the third encapsulation layer 153, and the first touch buffer layer 161 disposed under the second touch electrode line 182a.

Specifically, the touch interlayer insulating layer 163 includes an organic insulating material. Accordingly, even when moisture or oxygen penetrates, the touch interlayer insulating layer 163 may play a role in delaying the movement speed of moisture or oxygen.

The second touch buffer layer 162 includes an inorganic insulating material. Accordingly, even when moisture or oxygen penetrates through the touch interlayer insulating layer 163, it is possible to suppress the penetration of moisture or oxygen into the components positioned below the second touch buffer layer 162.

In addition, the second touch electrode line 182a is disposed in the dam area DA. Therefore, it is possible to suppress damage to the first encapsulation layer 151, the third encapsulation layer 153, and the first touch buffer layer 161, as well as damage to the second touch buffer layer 162 and the touch interlayer insulating layer 163 disposed under the second touch electrode line 182a.

Specifically, in the non-active area NA, in the area where the second touch electrode line 182a is not disposed, there is no photoresist to block plasma in the dry etching process. Accordingly, damage to the second touch buffer layer 162 and the touch interlayer insulating layer 163 may occur in the area where the second touch electrode line 182a is not disposed.

When damage occurs to the second touch buffer layer 162 and the touch interlayer insulating layer 163 and moisture or oxygen penetrates, the possibility of moisture or oxygen penetrating into the first encapsulation layer 151, the third encapsulation layer 153, and the first touch buffer layer 161 disposed below the second touch buffer layer 162 may increase.

However, in the display device 100 according to one embodiment of the present disclosure, the second touch electrode line 182a is disposed on the first encapsulation layer 151, the third encapsulation layer 153, and the first touch buffer layer 161 disposed on the first dam DAM1 and second dam DAM2, and the second touch buffer layer 162 and the touch interlayer insulating layer 163. Therefore, in the process of forming the second touch electrode line 182a, it is possible to suppress a defect in which moisture or oxygen is penetrated through the first encapsulation layer 151, the third encapsulation layer 153, and the first touch buffer layer 161, the second touch buffer layer 162, and the touch interlayer insulating layer 163.

In addition, as mentioned above, the first touch electrode line 181a is disposed between the first touch buffer layer 161 and the second touch buffer layer 162 on the first dam DAM1 and the second dam DAM2. Therefore, even when a gap is generated in the second touch buffer layer 162 or the touch interlayer insulating layer 163 and moisture or oxygen penetrates, the first touch electrode line 181a may serve to suppress the penetration of moisture or oxygen into the first encapsulation layer 151, the third encapsulation layer 153, and the first touch buffer layer 161 disposed below the first touch electrode line 181a.

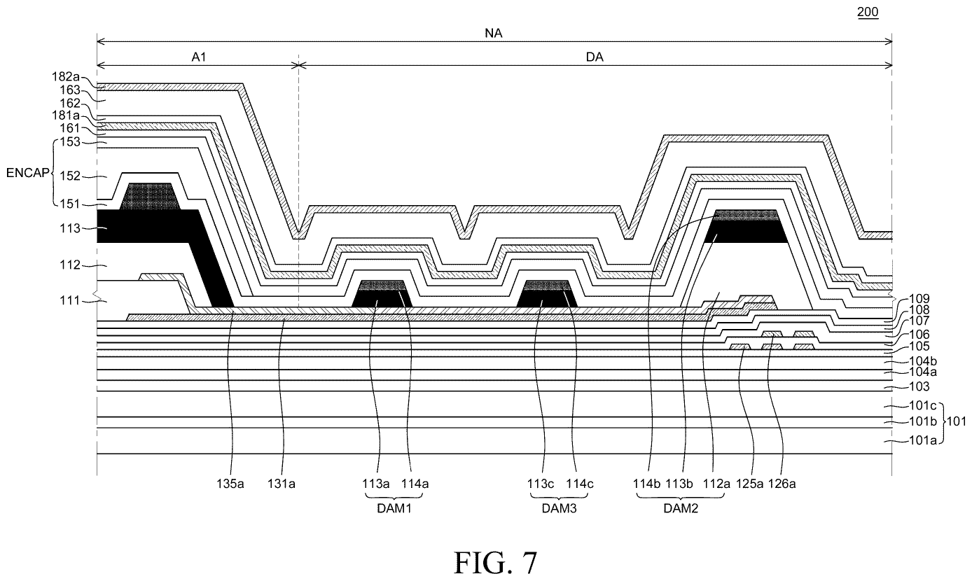

FIG. 7 is a cross-sectional view illustrating a non-active area of a display device according to another embodiment of the present disclosure.

A display device 200 of FIG. 7 is different from the display device 100 of FIG. 5 in that a third dam DAM3 is further disposed in the dam area DA, and the other components are substantially the same, so a duplicate description is omitted.

Referring to FIG. 7, the dam area DA may be disposed in the non-active area NA of the display device 200.

The third dam DAM3 may be disposed between the first dam DAM1 and the second dam DAM2 in the dam area DA.

In this way, by placing the third dam DAM3 between the first dam DAM1 and the second dam DAM2, even when the first dam DAM1 may not suppress the overflowing of the material of the second encapsulation layer 152 to the dam area DA, the second dam DAM2 may suppress the overflowing of the material of the second encapsulation layer 152.

The third dam DAM3 may be formed through a process of forming the bank 113 and the spacer 114.

The third dam DAM3 may include a third bank pattern 113c disposed on the second base wiring 135a and a third spacer pattern 114c disposed on the third bank pattern 113c.

In FIG. 7, the third dam DAM3 is illustrated as having a structure including the third bank pattern 113c and the third spacer pattern 114c, but is not limited thereto. For example, the third bank pattern 113c and the third spacer pattern 114c may be formed integrally.

On the third dam DAM3, the first encapsulation layer 151, the third encapsulation layer 153, the first touch buffer layer 161, the first touch electrode line 181a, the second touch buffer layer 162, the touch interlayer insulating layer 163, and the second touch electrode line 182a may be sequentially laminated.

In addition, the first touch electrode line 181a is disposed on the third dam DAM3. Therefore, it is possible to suppress damage to the first encapsulation layer 151, the third encapsulation layer 153, and the first touch buffer layer 161 in the process of forming the first touch electrode line 181a and the first touch electrode 181.

In addition, the second touch buffer layer 162 and the touch interlayer insulating layer 163 are disposed on the third dam DAM3. Therefore, the second touch buffer layer 162 and the touch interlayer insulating layer 163 may act as additional encapsulation layers to suppress the penetration of moisture or oxygen from the outside.

In addition, the second touch electrode line 182a is disposed on the third dam DAM3. Therefore, it is possible to suppress damage to the first encapsulation layer 151, the third encapsulation layer 153, the first touch buffer layer 161, the second touch buffer layer 162, and the touch interlayer insulating layer 163 in the process of forming the second touch electrode line 182a and the second touch electrode 182.

Accordingly, since it is possible to suppress the penetration of moisture or oxygen into the plurality of light-emitting diodes ED disposed in the active area AA, there is an effect of extending the lifespan of the light-emitting diodes ED. Accordingly, the display device 200 may be driven with low power.

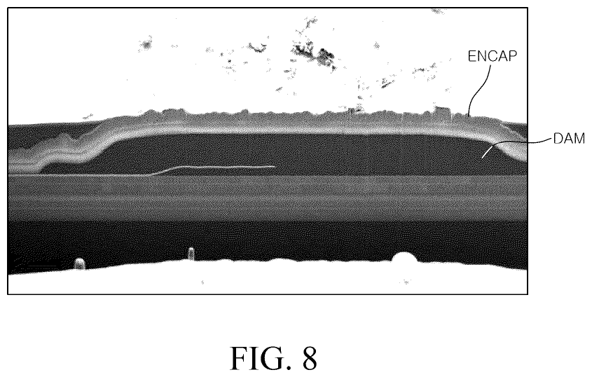

FIG. 8 is an image illustrating a portion of a dam area of a display device according to a comparative example.

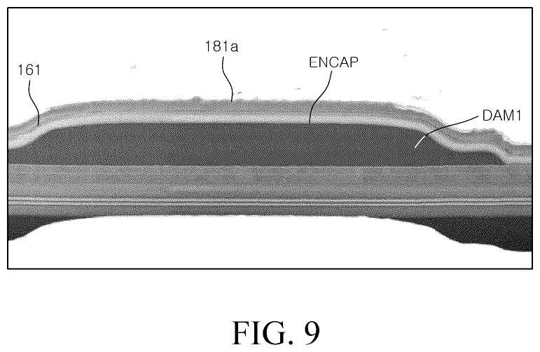

FIG. 9 is an image illustrating a portion of a dam area of a display device according to an embodiment.

The display device according to the comparative example of FIG. 8 has a structure in which the encapsulation layer is disposed on the dam. Here, the display device according to the comparative example may include a plurality of touch electrodes disposed in the active area.

FIG. 9 is an enlarged view of only a portion of the structure of the dam area DA of FIG. 5. Specifically, FIG. 9 illustrates a structure in which the first encapsulation layer 151, the third encapsulation layer 153, the first touch buffer layer 161, and the first touch electrode line 181a are disposed on the first dam DAM1.

First, referring to FIG. 8, it may be seen that damage has occurred on the surface of the encapsulation layer ENCAP positioned on the dam DAM. Specifically, during the process of forming a plurality of touch electrodes, damage may occur to the encapsulation layer ENCAP positioned on the dam DAM.

In this case, a moisture permeation path may be formed in the encapsulation layer, and moisture may infiltrate due to the moisture permeation path formed in the encapsulation layer.

Moisture that has penetrated through the moisture permeation path formed in the encapsulation layer ENCAP disposed on the dam DAM reaches the light-emitting diode ED of the active area AA, and the lifespan of the light-emitting diode ED may be reduced. As a result, it may become difficult to operate the display device with low power consumption.

Meanwhile, referring to FIG. 9, it may be seen that the encapsulation layer ENCAP is disposed on the first dam DAM1, the first touch buffer layer 161 is disposed on the encapsulation layer ENCAP, and the first touch electrode line 181a is disposed on the first touch buffer layer 161. Accordingly, it may be seen that there is no damage to the encapsulation layer ENCAP.

Accordingly, it is possible to suppress the penetration of moisture through the encapsulation layer ENCAP disposed in the non-active area NA, and thus, it is possible to suppress shortening of the lifespan of the light-emitting diode ED. Accordingly, there is an effect of being able to drive the display device with low power consumption.

The exemplary embodiments of the present disclosure can also be described as follows:

According to an aspect of the present disclosure, there is provided a display device. The display device includes a substrate including an active area and a non-active area positioned around the active area and including a dam area, at least one dam being disposed in the dam area. The display device further includes an encapsulation layer disposed in the active area and the dam area on the substrate. The display device further includes a first touch buffer layer disposed on the encapsulation layer in the dam area. The display device further includes a first touch electrode line disposed on the first touch buffer layer in the dam area. The display device further includes a second touch buffer layer disposed on the first touch electrode line in the dam area. The display device further includes a touch interlayer insulating layer disposed on the second touch buffer layer in the dam area. The display device further includes a second touch electrode line disposed on the touch interlayer insulating layer in the dam area. The second touch buffer layer includes an inorganic insulating material, and the touch interlayer insulating layer includes an organic insulating material.

The non-active area may further include an additional area disposed between the active area and the dam area, and the first touch buffer layer may be further disposed in the active area and the additional area.

The encapsulation layer may include a first encapsulation layer and a third encapsulation layer, the first encapsulation layer may be disposed on the at least one dam in the dam area, the third encapsulation layer may be disposed on the first encapsulation layer in the dam area, and the first touch buffer layer may be disposed on the at least one dam, the first encapsulation layer, and the third encapsulation layer in the dam area.

The non-active area may further include an additional area disposed between the active area and the dam area, and the first touch electrode line may be further disposed in the additional area, a first touch electrode is disposed in the active area, and the first touch electrode is connected to the first touch electrode line.

The encapsulation layer may include a first encapsulation layer and a third encapsulation layer, the first encapsulation layer may be disposed on at least one dam in the dam area, and the third encapsulation layer may be disposed on the first encapsulation layer in the dam area, and the first touch electrode line may be disposed on the at least one dam, the first encapsulation layer, the third encapsulation layer, and the first touch buffer layer in the dam area.

The non-active area may further include an additional area disposed between the active area and the dam area, and the second touch buffer layer may be further disposed in the active area and the additional area.

The encapsulation layer may include a first encapsulation layer and a third encapsulation layer, the first encapsulation layer may be disposed on the at least one dam in the dam area, and the third encapsulation layer is disposed on the first encapsulation layer in the dam area, and the second touch buffer layer may be disposed on the at least one dam, the first encapsulation layer, the third encapsulation layer, the first touch buffer layer, and the first touch electrode line in the dam area.

The non-active area may further include an additional area disposed between the active area and the dam area, and the touch interlayer insulating layer may be further disposed in the active area and the additional area.

The encapsulation layer may include a first encapsulation layer and a third encapsulation layer, the first encapsulation layer may be disposed on at least one dam in the dam area, and the third encapsulation layer may be disposed on the first encapsulation layer in the dam area, and the touch interlayer insulating layer may be disposed on the at least one dam, the first encapsulation layer, the third encapsulation layer, the first touch buffer layer, the first touch electrode line, and the second touch buffer layer in the dam area.

The non-active area may further include an additional area disposed between the active area and the dam area, and the second touch electrode line may be further disposed in the additional area,, a second touch electrode is disposed in the active area, and the second touch electrode is connected to the second touch electrode line.

The encapsulation layer may include a first encapsulation layer and a third encapsulation layer, the first encapsulation layer may be disposed on the at least one dam in the dam area, and the third encapsulation layer may be disposed on the first encapsulation layer in the dam area, and the second touch electrode line may be disposed on the at least one dam, the first encapsulation layer, the third encapsulation layer, the first touch buffer layer, the first touch electrode line, the second touch buffer layer, and the touch interlayer insulating layer in the dam area.

The display device may further include at least one base wiring disposed on the substrate in the non-active area, wherein the at least one dam is disposed on the at least one base wiring in the dam area.

The dam may include a first dam and a second dam spaced apart from the first dam, the first dam may be disposed on the substrate and may include the same material as a bank disposed in the active area, and the second dam may include a planarization layer pattern disposed on the substrate and including the same material as a planarization layer disposed in the active area, and a bank pattern disposed on the planarization layer pattern and including the same material as the bank disposed in the active area.

The dam may further include a third dam disposed between the first dam and the second dam, and the third dam may be disposed on the substrate and is disposed on the same layer as the bank disposed in the active area.

A height of the second dam may be higher than a height of the first dam.

According to another aspect of the present disclosure, there is provided a display device. The display device includes a substrate including an active area and a dam area positioned around the active area and having at least one dam disposed in the dam area. The display device further includes an encapsulation layer disposed in the active area and the dam area on the substrate. The display device further includes a first touch buffer layer disposed on the encapsulation layer. The display device further includes a first touch electrode line disposed on the first touch buffer layer. The display device further includes a second touch buffer layer disposed on the first touch electrode line. The display device further includes a touch interlayer insulating layer disposed on the second touch buffer layer. The display device further includes a second touch electrode line disposed on the touch interlayer insulating layer. The encapsulation layer, the first touch buffer layer, the first touch electrode line, the second touch buffer layer, the touch interlayer insulating layer, and the second touch electrode line each overlap a side surface and a top surface of the at least one dam.

The encapsulation layer may include a first encapsulation layer and a third encapsulation layer, the first encapsulation layer may be disposed on the at least one dam in the dam area, and the third encapsulation layer may be disposed on the first encapsulation layer in the dam area, and the first touch buffer layer may be disposed on the third encapsulation layer in at least a portion of the dam area.

The second touch buffer layer may include an inorganic insulating material, and the touch interlayer insulating layer may include an organic insulating material.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including an active area and a non-active area adjacent to the active area, the non-active area including a dam area, at least one dam being disposed in the dam area;
an encapsulation layer disposed on the substrate in the active area and extending into the dam area;
a first touch buffer layer disposed on the encapsulation layer and extending into the dam area;
a first touch electrode line disposed on the first touch buffer layer and extending into the dam area;
a second touch buffer layer disposed on the first touch electrode line and extending into the dam area;
a touch interlayer insulating layer disposed on the second touch buffer layer and extending into the dam area; and
a second touch electrode line disposed on the touch interlayer insulating layer and extending into the dam area,
wherein the second touch buffer layer includes an inorganic insulating material, and the touch interlayer insulating layer includes an organic insulating material.

2. The display device according to claim 1, wherein the non-active area further includes an additional area disposed between the active area and the dam area, and
wherein the first touch buffer layer is further disposed in the active area and the additional area.

3. The display device according to claim 2, wherein the encapsulation layer includes a first encapsulation layer, a second encapsulation layer, and a third encapsulation layer,
wherein the first encapsulation layer is disposed on the at least one dam in the dam area,
wherein the third encapsulation layer is disposed on the first encapsulation layer in the dam area, and
wherein the first touch buffer layer is disposed on the at least one dam, the first encapsulation layer, and the third encapsulation layer in the dam area.

4. The display device according to claim 1, wherein the non-active area further includes an additional area disposed between the active area and the dam area, and
wherein the first touch electrode line is further disposed in the additional area, a first touch electrode is disposed in the active area, and the first touch electrode is connected to the first touch electrode line.

5. The display device according to claim 4, wherein the encapsulation layer includes a first encapsulation layer, a second encapsulation layer, and a third encapsulation layer,
wherein the first encapsulation layer is disposed on at least one dam in the dam area, and the third encapsulation layer is disposed on the first encapsulation layer in the dam area, and
wherein the first touch electrode line is disposed on the at least one dam, the first encapsulation layer, the third encapsulation layer, and the first touch buffer layer in the dam area.

6. The display device according to claim 1, wherein the non-active area further includes an additional area disposed between the active area and the dam area, and
wherein the second touch buffer layer is further disposed in the active area and the additional area.

7. The display device according to claim 6, wherein the encapsulation layer includes a first encapsulation layer, a second encapsulation layer, and a third encapsulation layer,
wherein the first encapsulation layer is disposed on the at least one dam in the dam area, and the third encapsulation layer is disposed on the first encapsulation layer in the dam area, and
wherein the second touch buffer layer is disposed on the at least one dam, the first encapsulation layer, the third encapsulation layer, the first touch buffer layer, and the first touch electrode line in the dam area.

8. The display device according to claim 1, wherein the non-active area further includes an additional area disposed between the active area and the dam area, and
wherein the touch interlayer insulating layer is further disposed in the active area and the additional area.

9. The display device according to claim 8, wherein the encapsulation layer includes a first encapsulation layer, a second encapsulation layer, and a third encapsulation layer,
wherein the first encapsulation layer is disposed on at least one dam in the dam area, and the third encapsulation layer is disposed on the first encapsulation layer in the dam area, and
wherein the touch interlayer insulating layer is disposed on the at least one dam, the first encapsulation layer, the third encapsulation layer, the first touch buffer layer, the first touch electrode line, and the second touch buffer layer in the dam area.

10. The display device according to claim 1, wherein the non-active area further includes an additional area disposed between the active area and the dam area, and
wherein the second touch electrode line is further disposed in the additional area, a second touch electrode is disposed in the active area, and the second touch electrode is connected to the second touch electrode line.

11. The display device according to claim 10, wherein the encapsulation layer includes a first encapsulation layer, a second encapsulation layer, and a third encapsulation layer,
wherein the first encapsulation layer is disposed on the at least one dam in the dam area, and the third encapsulation layer is disposed on the first encapsulation layer in the dam area, and
wherein the second touch electrode line is disposed on the at least one dam, the first encapsulation layer, the third encapsulation layer, the first touch buffer layer, the first touch electrode line, the second touch buffer layer, and the touch interlayer insulating layer in the dam area.

12. The display device according to claim 1, further comprising at least one base wiring disposed on the substrate in the non-active area,
wherein the at least one dam is disposed on the at least one base wiring in the dam area.

13. The display device according to claim 1, wherein the dam includes a first dam and a second dam spaced apart from the first dam,
wherein the first dam is disposed on the substrate and includes the same material as a bank disposed in the active area, and
wherein the second dam includes a planarization layer pattern disposed on the substrate and including the same material as a planarization layer disposed in the active area, and a bank pattern disposed on the planarization layer pattern and including the same material as the bank disposed in the active area.

14. The display device according to claim 13, wherein the dam further includes a third dam disposed between the first dam and the second dam, and
wherein the third dam is disposed on the substrate and is disposed on the same layer as the bank disposed in the active area.

15. The display device according to claim 13, wherein a height of the second dam is higher than a height of the first dam.

16. A display device comprising:
a substrate including an active area and a dam area adjacent to the active area, at least one dam disposed in the dam area;
an encapsulation layer disposed in the active area and the dam area on the substrate;
a first touch buffer layer disposed on the encapsulation layer;
a first touch electrode line disposed on the first touch buffer layer;
a second touch buffer layer disposed on the first touch electrode line;
a touch interlayer insulating layer disposed on the second touch buffer layer; and
a second touch electrode line disposed on the touch interlayer insulating layer,
wherein the encapsulation layer, the first touch buffer layer, the first touch electrode line, the second touch buffer layer, the touch interlayer insulating layer, and the second touch electrode line each overlap a side surface and a top surface of the at least one dam.

17. The display device according to claim 16, wherein the encapsulation layer includes a first encapsulation layer, a second encapsulation layer, and a third encapsulation layer,
wherein the first encapsulation layer is disposed on the at least one dam in the dam area, and the third encapsulation layer is disposed on the first encapsulation layer in the dam area, and
wherein the first touch buffer layer is disposed on the third encapsulation layer in at least a portion of the dam area.

18. The display device according to claim 16, wherein the second touch buffer layer includes an inorganic insulating material, and
wherein the touch interlayer insulating layer includes an organic insulating material.
